(19) United States
(12) Patent Application Publication
(10) Pub. No.: US 2018/0175782 A1
(43) Pub. Date: Jun. 21, 2018

(54) Support Structure for Maximizing Solar-Panel Efficiency and Facilitating Solar-Panel Installation

(71) Applicant: Sane Innovations, LLC., Madrid, NE (US)

(72) Inventor: Marlin W. Unruh, Madrid, NE (US)

(21) Appl. No.: 15/849,556

(22) Filed: Dec. 20, 2017

Related U.S. Application Data
(60) Provisional application No. 62/436,767, filed on Dec. 20, 2016.

(51) Int. Cl. H02S 20/10; H02S 30/10; H01L 31/042

(52) U.S. Cl. CPC H02S 20/10; H01L 31/042; H02S 30/10

(57) ABSTRACT

A support structure for maximizing solar-panel efficiency and facilitating solar-panel installation reduces the effort of installing solar-panels. The support structure includes a support pole, a primary panel-supporting bracket, an extension arm, and an extension leg. The support pole pivots about a first rotation axis to lower the primary panel-supporting bracket for the solar-panel installation process. The primary panel-supporting bracket is designed to support a variable number of solar-panels depending on the budget constraints and power generation demands. An extension arm raises the primary panel-supporting bracket over the support pole, allowing the primary panel-supporting bracket to rotate about the support pole. The extension leg secures the support structure to the ground and provides a fulcrum for the support pole to pivot about.

The current application claims a priority to the U.S. Provisional Patent application Ser. No. 62/436,767 filed on Dec. 20, 2017.

### FIELD OF THE INVENTION

The present invention generally relates to a support structure for maximizing solar-panel efficiency and facilitating solar-panel installation. More specifically, the present invention includes a support pole pivotally mounted to an extension leg for raising and lowering a primary panel-supporting bracket for the solar-panel installation process.

### BACKGROUND OF THE INVENTION

Photovoltaic (PV) solar-panels produce electrical power without emitting any pollutants or damaging the environment. Fossil fuels in contrast generate electricity by producing undesirable byproducts which contaminate the environment. Additionally, fossil fuels are a non-renewable and finite resource which cannot be replaced once used. Biofuels are renewable but use water resources which are diminishing in an area in which water is drawn from an underground source or aquifer. There are also energy inputs used to process the fuel from the plan matter, or other materials used to produce biofuels. Wind power can generate an endless supply of energy from a natural occurring source caused by uneven heating and cooling of the world. However, the wind is generated sporadically and is constantly changing. This can lead to an over production of electrical power when the demand for electrical power is not required.

Given the limitation of conventional energy generating methods, producing electrical power from sun light is the most logical and environmentally friendly. Among the many advantages of solar power is that the highest amount of solar energy is generated during the daylight hours when electrical power is generally in highest demand. Further, the solar energy is usually generated at the source of consumption, thereby obviating the need for costly transmission lines to transmit power from the production source to residential areas. Thus, solar energy can be used even where there is no municipal electrical power available. Excess solar energy that is generally stored in batteries for later use when the photo voltaic solar-panels are not producing electricity. The most common method of using solar produced electricity is placing the power into the municipal electrical power grid. Support poles and similar structures are used to suspended and position PV solar-panels facing the sun. There are many configurations for pole mounted solar-panel arrays. However, many of them are severely limited in ease-of-use and efficiency.

Conventional support structures for solar-panels requires the user to raise solar-panels one by one to install them onto a supporting bracket. Raising heavy solar-panels tens of feet over the ground is an inherently dangerous activity that requires planning and preparation. This makes the process of installing solar-panels vary laborious and dangerous.

Additionally, conventional support structures position the solar-panels at a 90-degree angle in relation to the ground. This creates a large obstacle to the natural flow of the wind, generating large drag forces on the support structure. Wind can exert an extreme amount of force on a support structure. For example, a 50 mile-an-hour wind gust striking a solar-panel in a flat plain configuration at a 90-degree angle can exert 6.4 pounds of force per square foot. At 100 miles per hour, the wind gust would exert 25.6 pounds per square foot or 14,790 pounds of force on an array of solar-panels. Most conventional support structure orient the solar-panels at angle to the ground to reduce the forces generated by the wind. However, this still creates a large pressure differential between the opposite sides of the solar-panels.

To remedy these limitations of conventional support structure, the present invention utilizes a support pole pivotally mounted onto an extension leg, that raises and lowers a solar-panel mounting bracket during the installation process. Further, the solar-panel mounting bracket can be expanded by using a plurality of supplementary brackets. The plurality of supplementary brackets is also configured with fluid-bypass gaps between adjacent rows of brackets to reduce air pressure on the solar-panels.

### BRIEF DESCRIPTION OF THE DRAWINGS

FIG. 1 is a front perspective view of the present invention.

FIG. 2 shows a front perspective view of the support pole being lowered for the solar-panel installation process.

FIG. 3 is a rear perspective view of the present invention.

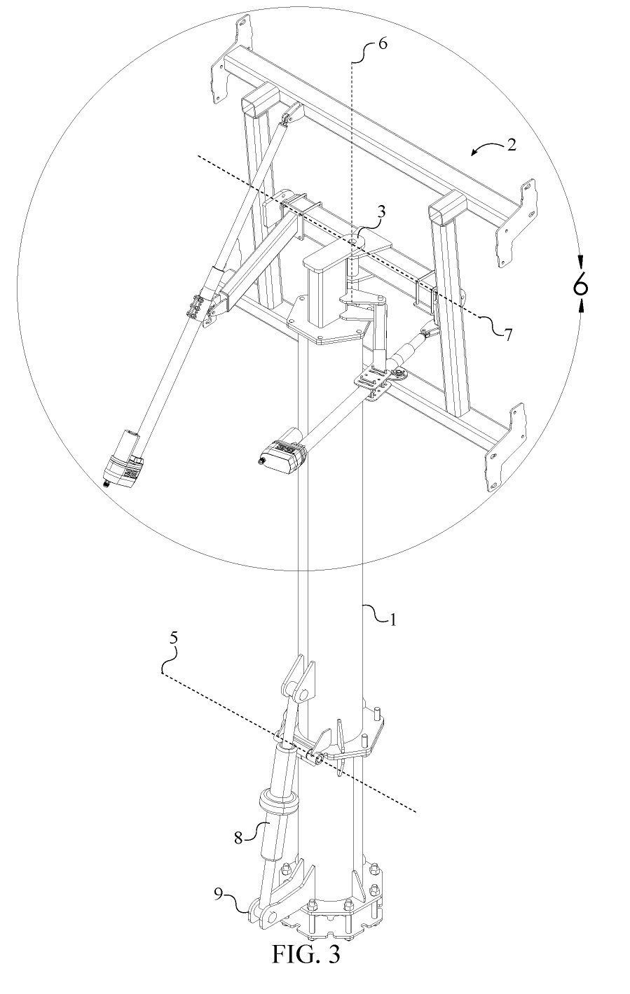

FIG. 4 is a detail view taken about circle 4 in FIG. 1 showing the subcomponents of the primary panel-supporting bracket.

FIG. 5 is a detail view taken about circle 5 in FIG. 2 showing the subcomponents of the primary panel-supporting bracket.

FIG. 6 is a detail view taken about circle 6 in FIG. 3 showing the second linear actuator engaged to the panel-mounting structure and the third linear actuator engaged to the alignment rod.

FIG. 7 is a front perspective view of the plurality of supplementary panel-supporting brackets mounted onto the primary panel-supporting bracket.

FIG. 8 is a perspective view illustrating rows of solar-panels mounted on to the plurality of supplementary panel-supporting brackets.

FIG. 9 is a side view illustrating a fluid-bypass gap created between the arbitrary row of panel-supporting brackets and the adjacent row of panel-supporting brackets.

### DETAILED DESCRIPTION OF THE INVENTION

All illustrations of the drawings are for the purpose of describing selected versions of the present invention and are not intended to limit the scope of the present invention.

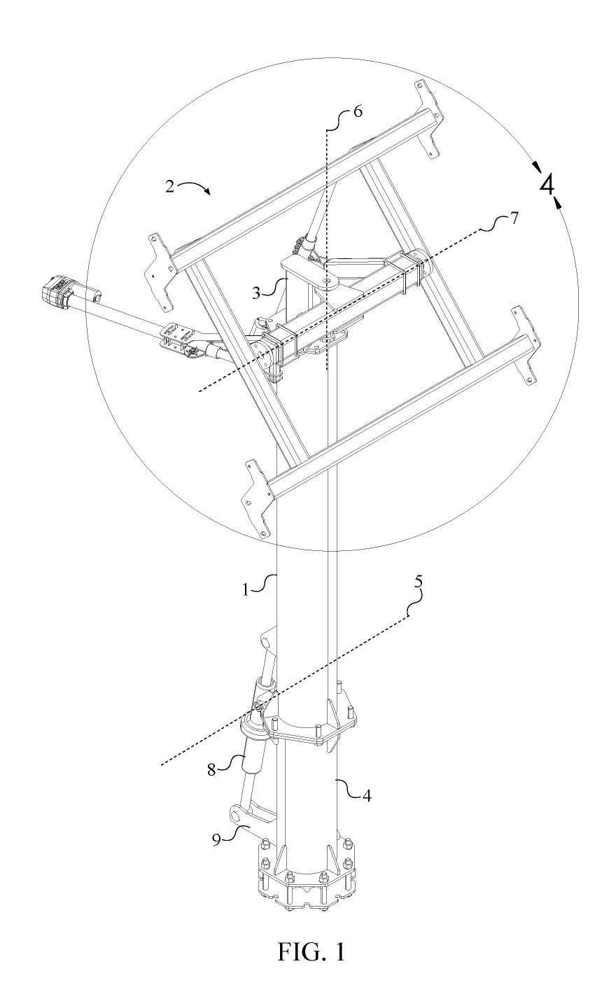

The present invention is a support structure for maximizing solar-panel efficiency and facilitating solar-panel installation. The present invention is designed to reduce aerodynamic drag and increase stability. Referring now to FIG. 1, the preferred embodiment of the present invention comprises a support pole 1, a primary panel-supporting bracket 2, an extension arm 3, and an extension leg 4. A plurality of bolts protruding out of a concrete pad help mount the extension leg 4 onto a concrete pad. Once mounted, the support pole 1 is terminally positioned to the extension leg 4. Further, the support pole 1 is hingedly connected to the extension leg 4 about a first rotation axis 5. The hinged connection allows the support pole 1 to pivot on the extension leg 4 about the first rotation axis 5. The support pole 1 can thus be lowered closer to the ground which eases the process of installing the solar-panels. Once the solar-panels are installed, the support pole 1 is raised back to the desired position. The first rotation axis 5 is positioned perpendicular to the support pole 1. Thus, in the raised position, the support pole 1 erects to a vertically straight position. The extension arm 3 is terminally connected to the support pole 1, opposite to the extension leg 4. The extension arm 3 raises the primary panel-supporting bracket 2 over the support pole, allowing the primary pane-supporting bracket 2 the full range of motion in the first rotation axis 5. Further, the primary panel-supporting bracket 2 is terminally positioned to the extension arm 3, opposite the support pole 1. The primary panel-supporting bracket 2 is designed to hold a plurality of solar-panels in an expandable manner.

Preferably, the plurality of solar-panels is configured to track the sun. Accordingly, the primary panel-supporting bracket 2 is pivotally mounted to the extension arm 3 about a second rotation axis 6 and a third rotation axis 7. In the preferred embodiment, the second rotation axis 6 allows the primary panel-supporting bracket 2 to rotate in the East-West direction, whereas the third rotation axis 7 allows rotation in the North-South direction. The second rotation axis 6 has a rotation range of 70-degrees in East-West direction. Preferably, the second rotation axis 6 is positioned parallel with the support pole 1. This allows the primary panel-supporting bracket 2 to track the sun as it travels across the sky in the East-West direction. The third rotation axis 7 is positioned perpendicular to the second rotation axis 6. As a result, the third rotation axis 7 allows the primary panel-supporting bracket 2 to rotate 90-degrees in the North-South direction. This range of rotation makes it advantageous for the present invention to be used at any latitude. Both the second rotation axis 6 and the third rotation axis 7 can rotate simultaneously, thus the 70-degree rotation range of the second rotation axis 6 is possible throughout the 90-degree rotation range of the third rotation axis 7.

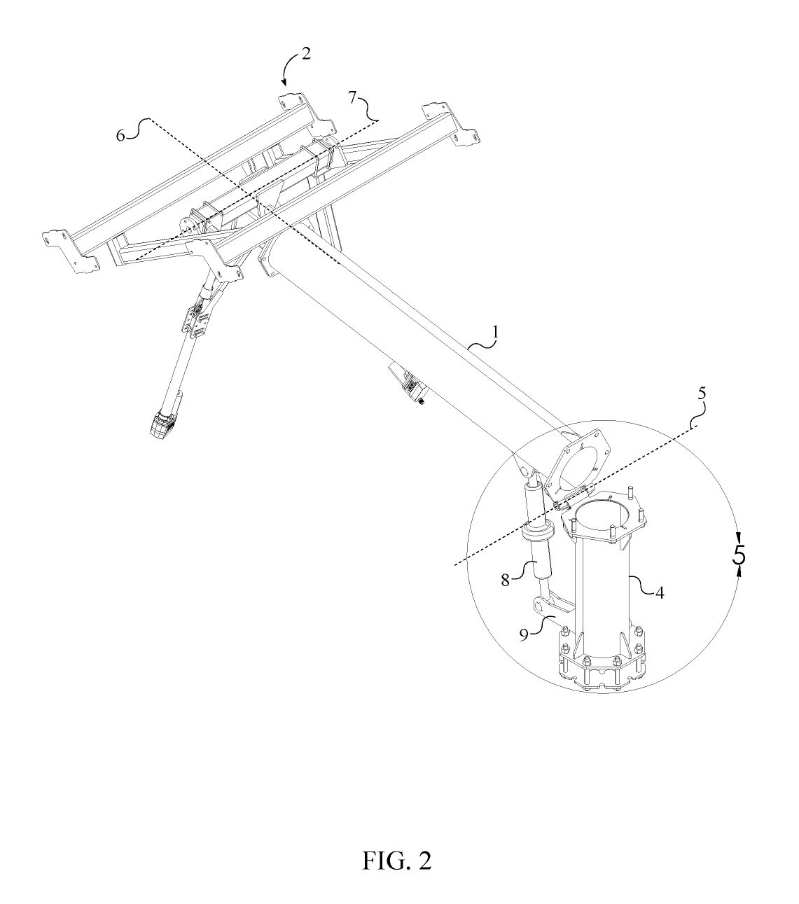

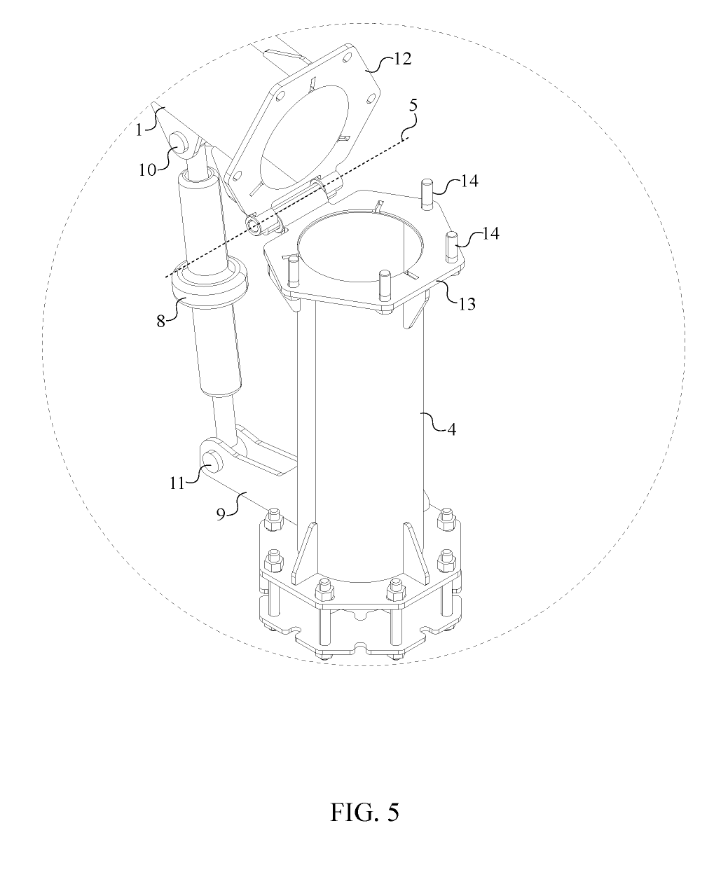

FIG. 2 and FIG. 5 shows a first linear actuator 8 used to lower and raise the support pole 1 before and after the solar-panel installation process. The preferred first linear actuator 8 may be a heavy-duty ratchet load binder jack, a hydraulic cylinder, an electrically powered linear actuator, or any similar device. An extension foot 9 is used to guide the movement of the support pole 1 about the first linear actuator 8 as the support pole 1 is raised or lowered to a desired position. The extension foot 9 is laterally connected to the extension leg 4, offset from the first rotation axis 5. Further, the extension foot 9 is positioned perpendicular to the first rotation axis 5. This forms an angle between the first linear actuator 8 and the support pole 1. The first linear actuator 8 is positioned perpendicular to the first rotation axis 5. Thus, when the first linear actuator 8 extends or retracts, a torque arm is generated about the first rotation axis 5 which forces the support pole 1 to rotate. A proximal end 10 of the first linear actuator 8 is hingedly and laterally attached to the support pole 1, offset from the first rotation axis 5. Similarly, a distal end 11 of the first linear actuator 8 is hingedly attached to the extension foot 9, offset from the extension leg 4. This allows the first linear actuator 8 to rotate about the extension foot 9 as the support pole 1 rotates about the first rotation axis 5. Further, as a security measure, the first linear actuator 8 can be detached and a solid arm padlocked into place, to prevent primary panel-supporting bracket 2 being lowered by an unauthorized person.

A first locking flange 12 and a second locking flange 13 affixes the support pole 1 in the straight vertical position. The first locking flange 12 is laterally connected around the support pole 1 Similarly, the second locking flange 13 is laterally connected around the extension leg 4. Both the first locking flange 12 and the second locking flange 13 comprises a pin eye fixed. A hinge is formed by pivotally engaged the pin eyes of the first locking flange 12 and the second locking flange 13. When the support pole 1 is pivoted to lower the primary panel-supporting bracket 2, the first locking flange 12 and the second locking flange 13 separate. When the support pole 1 is in the vertically straight position, the first locking flange 12 and the second locking flange 13 are pressed against each other. A plurality of fasteners 14 is installed to securely fix the support pole 1 to the extension leg 4. More precisely, the first locking flange 12 and the second locking flange 13 are engaged to each other by the plurality of fasteners 14. Preferably, the plurality of fasteners 14 is raised bolts installed into holes in both the first locking flange 12 and the second locking flange 13.

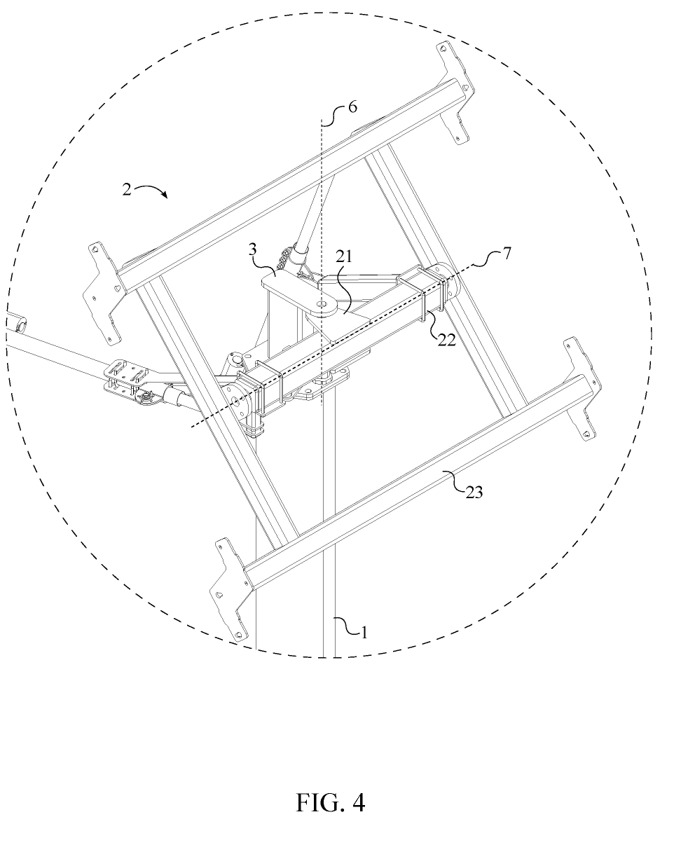

FIG. 4 shows the extension arm 3 positioned collinear with the support pole 1. This positions the second rotation axis 6 proximal to the support pole 1 and reduces the overall length of the extension arm 3, thereby reducing compound forces acting on the extension pole. Further, the proximal positioning of the second rotation axis 6 and the support pole 1 reduces bend forces generated by wind gust hitting the primary panel-supporting bracket 4.

Referring once more to FIG. 4, the primary panel-supporting bracket 2 comprises a clevis 21, an alignment rod 22, and a panel-mounting structure 23. The clevis 21 creates a hinged connection between the primary panel-supporting bracket 2 to the extension arm 3. Accordingly, the clevis 21 is terminally connected to the extension arm 3, opposite the support pole 1. In the preferred embodiment, the clevis 21 comprises tabs that engage the alignment rod 22. Pins rotatably connect the clevis 21 to the extension arm 3. Preferably, the second rotation axis 6 traverses through the pins and the tabs of the clevis 21. Further, the alignment rod 22 is rotatably connected into the clevis 21 about the second rotation axis 6. As such, the primary panel-supporting bracket 2 rotates in the East-West direction about the alignment rod 22. The clevis 21 preferably connects to the center of the alignment rod 22 which corresponds to the transverse center of gravity of the primary panel-supporting bracket 2, thereby ensuring stability in the transverse direction. Similarly, the panel-mounting structure 23 is rotatably connected to the alignment rod 22 about the third rotation axis 7. The panel-mounting structure 23 allows a plurality of solar-panels to be releasably mounted onto the primary panel-supporting bracket 2. The alignment rod 22 connects through tabs located in the longitudinal center of the panel-mounting structure 23 which corresponds to the longitudinal center of gravity of the panel-mounting structure 23. Thus, the panel-mounting structure 23 is placed in equilibrium in both the transverse and the longitudinal direction. Pins rotatably connect the alignment rod 22 onto the tabs of the panel-mounting structure 23. The third rotation axis 7 traverses through the pins of the panel-mounting structure 23 and the alignment rod 22. This allows the panel-mounting structure 23 to rotate in the North-South direction.

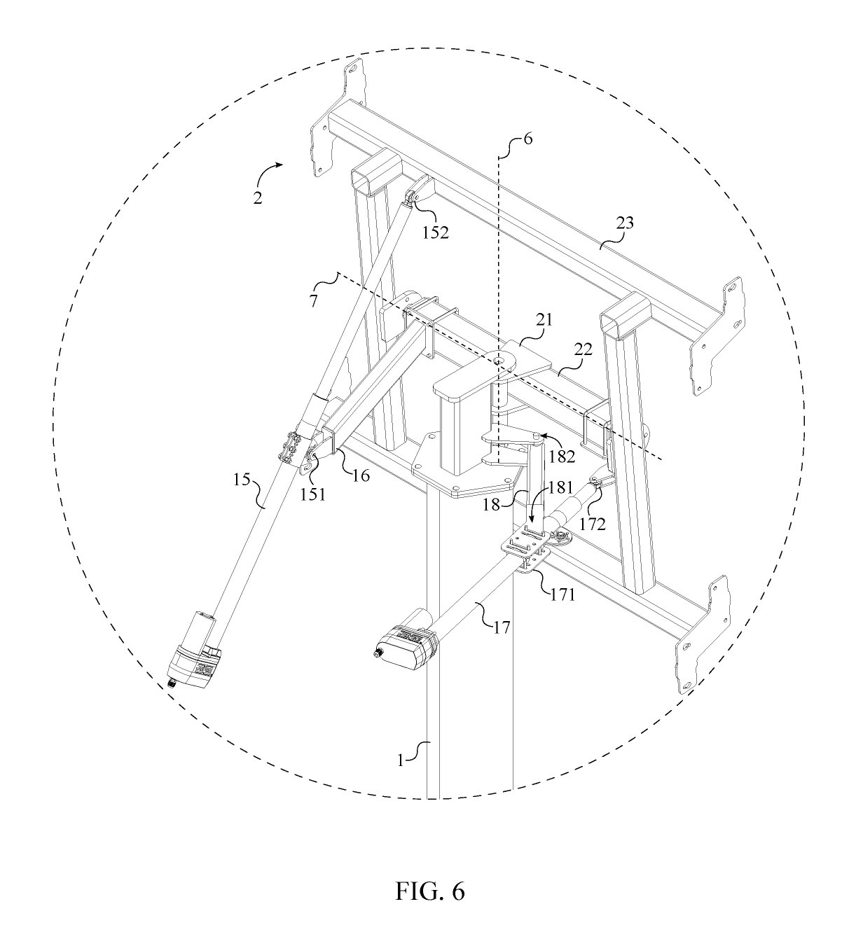

As can be seen in FIG. 6, a second linear actuator 15 generates a torque arm for rotating the primary panel-supporting bracket 2 about the third rotation axis 7. More specifically, a spacing rod 16 allows the second linear actuator 15 to generate a torque arm which forces the primary panel-supporting bracket 2 to rotate about the third rotation axis 7. As such, the spacing rod 16 is laterally connected to the alignment rod 22, offset from the clevis 21. A proximal end 151 of the second linear actuator 15 is hingedly and laterally attached to the spacing rod 16, offset from the alignment rod 22. Further, a distal end 152 of the second linear actuator 15 is hingedly attached to the panel-mounting structure 23, offset from the alignment rod 22. The second linear actuator 15 must rotate to ensure the distal end 152 remains attached to the panel-mounting structure 23 throughout the rotation range. As a result, the spacing rod 16 connects the second linear actuator 15 to the panel-mounting structure 23 at an angle, thereby generating a torque arm about the third rotation axis 7.

In the preferred embodiment of the present invention, the second linear actuator 15 is electrically actuated. Alternately, the second linear actuator 15 may be replaced with a fixed shaft for affixing the primary panel-supporting bracket 2. Alternately, the second linear actuator 15 may be a ratcheting turnbuckle jack for manual adjustment.

Referring once more to FIG. 6, a third linear actuator 17 generates a torque arm for rotating the alignment rod 22 about the second rotation axis 6. Further, the third linear actuator 17 is connected in a manner that allows translational and rotational freedom. More specifically, a swivel arm 18 allows the third linear actuator 17 to translate and rotate about the extension arm 3. As such, a first end 181 of the swivel arm 18 is hingedly and laterally connected to the extension arm 3 Likewise, a second end 182 of the swivel arm 18 is laterally connected to the third linear actuator 17. The swivel arm 18 swivels about the extension arm 3 to reorient the third linear actuator 17 as the alignment rod 22 rotates. This allows the third linear actuator 17 to remain attached to the extension arm 3 and the panel-mounting structure 23, as the primary panel-supporting bracket rotates 2 about the second rotation axis 6. Accordingly, the second end 182 of the swivel arm 18 is positioned adjacent to a proximal end 171 of the third linear actuator 17, offset from the second rotation axis 6. A distal end 172 of the third linear actuator 17 is hingedly and laterally attached to the alignment rod 22, offset from the second rotation axis 6. Thus, as the alignment rod 22 rotates about the second rotation axis 6, the third linear actuator 17 freely translates and rotates about the extension arm 3.

As with the second linear actuator 15, the preferred third linear actuator 17 is electrically actuated. Alternately, the third linear actuator 17 may be a fixed shaft for affixing the alignment rod 22, a ratcheting turnbuckle jack for manual adjustment, or some other manner of mechanical actuator.

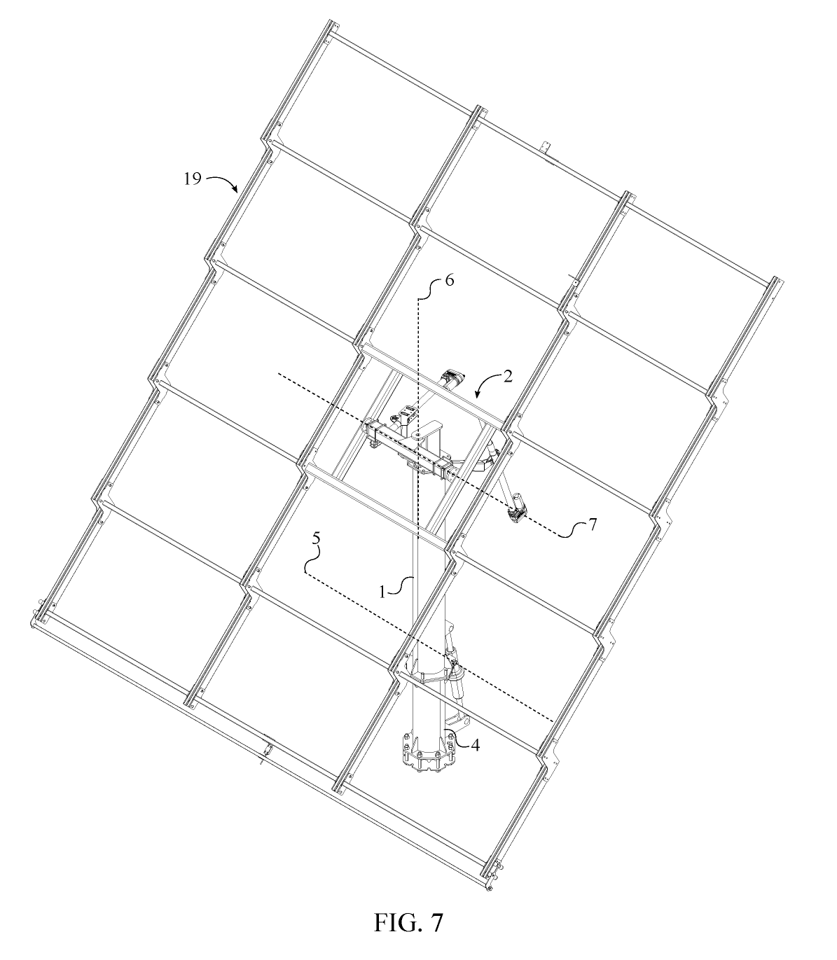

In reference to FIG. 7, the preferred embodiment of the present invention, the primary panel-supporting bracket 2 is expandable to support additional solar-panels as the owner's budget allows, or the need for greater amount of electrical power arises. More precisely, a plurality of supplementary panel-supporting brackets 19 mounts a variable number of solar-panels onto the primary panel-supporting bracket 2. Preferably, the plurality of supplementary panel-supporting brackets 19 is arranged in a grid configuration around the primary panel-supporting bracket 2. The plurality of supplementary panel-supporting brackets 19 can be configured to support a maximum of 20 solar-panels. Further, the solar-panels may be arranged in extending in the transverse direction or the longitudinal direction to the support pole 1. Each of the plurality of supplementary panel-supporting brackets 19 comprises cross-ties and at least spacing tubes. The cross ties are used to expand the primary panel-supporting bracket 2 in the transverse direction to the support pole 1, whereas the spacing tubes are used to expand the primary panel-supporting bracket 2 in the longitudinal direction.

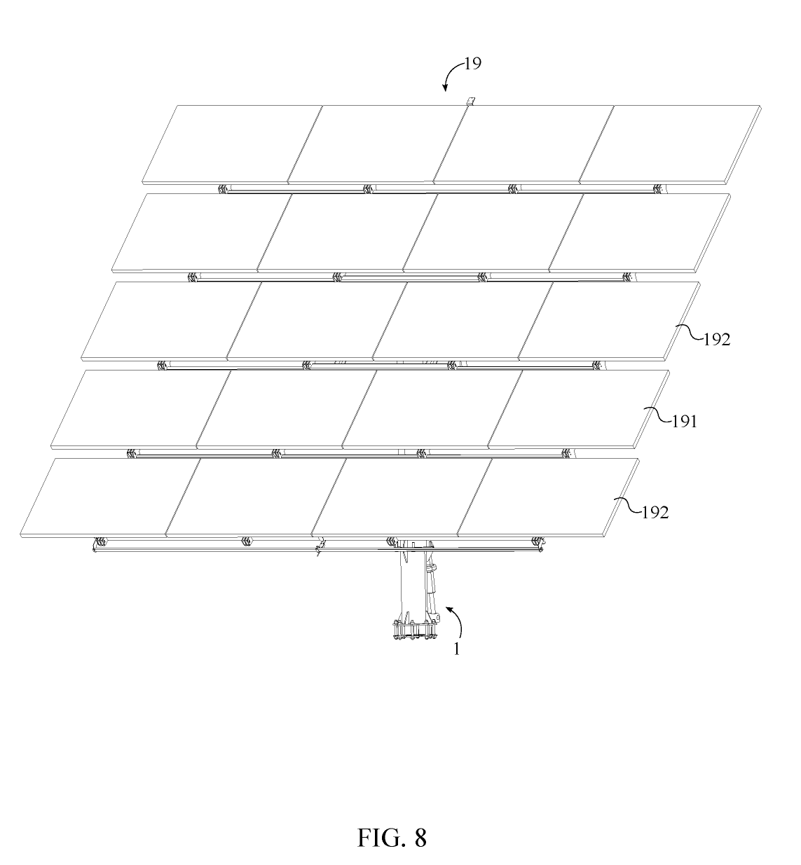

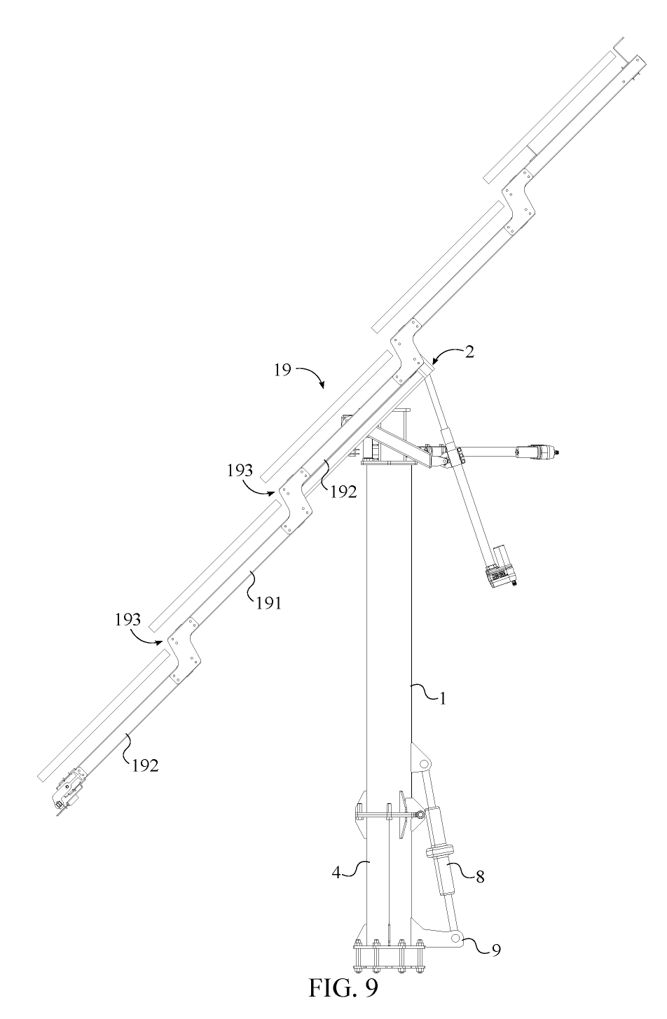

As can be seen in FIG. 8 and FIG. 9, in the preferred embodiment of the present invention, an arbitrary row of panel-supporting brackets 191 from the grid configuration is positioned coplanar to each other. As a result, the solar-panels mounted onto the arbitrary row of panel-supporting brackets 191 are coincident to each other. Further, the solar-panels are mounted in a manner which eliminates any gap between two coincidently placed solar-panels. Similarly, an adjacent row of panel-supporting brackets 191 from the grid configuration is positioned coplanar to each other. This creates row of solar-panels positioned adjacent to each other, extending along the transverse direction of the support pole 1. Further, the arbitrary row of panel-supporting brackets 191 and the adjacent row of panel-supporting brackets 191 are positioned offset from each other by a fluid-bypass gap 193. The arbitrary row of panel-supporting brackets 191 and the adjacent row of panel-supporting brackets 192 can be any pair of adjacent rows from the grid configuration. As a result, an arbitrary row of solar-panels is also offset in a stepped fashion from an adjacent row of solar-panels. The fluid-bypass gap 193 allows air to flow past the rows of solar-panels. Wind gusts hitting the rows of solar-panels generate drag forces which exert a bending force on the both the primary panel-supporting bracket 2 and the support pole 1. This can cause present invention to collapse and break. Wind can exert extreme amount of force on the rows of solar-panels. For example, a 50 miles-per-hour wind gust striking the rows of solar-panels oriented at 90-degrees to the horizontal can exert 6.4 pounds of force per square foot. On typical sized solar-panels, this generates a force of 230 pounds on the face of the rows of solar-panels. Thus, the plurality of supplementary panel-supporting brackets 19 is angled in relation to the support pole 1. Further, the use of a fluid-bypass gap 193 between the arbitrary row of panel-supporting brackets 191 and the adjacent row of panel-supporting brackets 192 greatly reduces the forces acting on the support pole 1. This allows wind to move upward across the face of the rows of solar-panels and exit through the fluid-bypass gap 193, thereby reducing the pressure differential between the front of the solar-panels and the rear. The cumulative effect of the angled primary panel-supporting bracket 2 and the fluid-bypass gap 193 between the arbitrary row of panel-supporting brackets 191 and the adjacent row of panel-supporting brackets 192 greatly reduces the bending forces acting on the support pole 1.

Although the invention has been explained in relation to its preferred embodiment, it is to be understood that many other possible modifications and variations can be made without departing from the spirit and scope of the invention as hereinafter claimed.

What is claimed is:

1. A support structure for maximizing solar-panel efficiency and facilitating solar-panel installation comprises:
a support pole;
a primary panel-supporting bracket;
an extension arm;
an extension leg;
the support pole being terminally positioned to the extension leg;
the support pole being hingedly connected to the extension leg about a first rotation axis;
the first rotation axis being positioned perpendicular to the support pole;
the extension arm being terminally connected to the support pole, opposite to the extension leg;
the primary panel-supporting bracket being terminally positioned to the extension arm, opposite the support pole;
the primary panel-supporting bracket being pivotally mounted to the extension arm about a second rotation axis and a third rotation axis;
the second rotation axis being positioned parallel with the support pole; and
the third rotation axis being positioned perpendicular to the second rotation axis.

2. The support structure for maximizing solar-panel efficiency and facilitating solar-panel installation as claimed in claim 1 comprises:
a first linear actuator;
an extension foot;
the extension foot being laterally connected to the extension leg, offset from the first rotation axis;
the extension foot being positioned perpendicular to the first rotation axis;
the first linear actuator being positioned adjacent to the first rotation axis;
a proximal end of the first linear actuator being hingedly and laterally attached to the support pole, offset from the first rotation axis; and
a distal end of the first linear actuator being hingedly attached to the extension foot, offset from the extension leg.

3. The support structure for maximizing solar-panel efficiency and facilitating solar-panel installation as claimed in claim 1 comprises:
a first locking flange;
a second locking flange;
the first locking flange being laterally connected around the support pole;
the second locking flange being laterally connected around the extension leg; and
the first locking flange and the second locking flange being pressed against each other.

4. The support structure for maximizing solar-panel efficiency and facilitating solar-panel installation as claimed in claim 3 comprises:
a plurality of fasteners; and
the first locking flange and the second locking flange being engaged to each other by the plurality of fasteners.

5. The support structure for maximizing solar-panel efficiency and facilitating solar-panel installation as claimed in claim 1 comprises:
the extension arm being positioned collinear with the support pole.

6. The support structure for maximizing solar-panel efficiency and facilitating solar-panel installation as claimed in claim 1 comprises:
the primary panel-supporting bracket comprises a clevis, an alignment rod, and a panel-mounting structure;
the clevis being connected adjacent to extension arm, offset the support pole;
the alignment rod being rotatably connected into the clevis about the second rotation axis; and
the panel-mounting structure being rotatably connected to the alignment rod about the third rotation axis.

7. The support structure for maximizing solar-panel efficiency and facilitating solar-panel installation as claimed in claim 6 comprises:
a second linear actuator;
a spacing rod;
the spacing rod being laterally connected to the alignment rod, offset from the clevis;
a proximal end of the second linear actuator being hingedly and laterally attached to the spacing rod, offset from the alignment rod; and
a distal end of the second linear actuator being hingedly attached to the panel-mounting structure, offset from the alignment rod.

8. The support structure for maximizing solar-panel efficiency and facilitating solar-panel installation as claimed in claim 6 comprises:
a third linear actuator;
a swivel arm;
a first end of the swivel arm being hingedly and laterally connected to the extension arm;
a second end of the swivel arm being laterally connected to the third linear actuator;
the second end of the swivel arm being positioned adjacent to a proximal end of the third linear actuator, offset from the second rotation axis; and
a distal end of the third linear actuator being hingedly and laterally attached to the alignment rod, offset from the second rotation axis.

9. The support structure for maximizing solar-panel efficiency and facilitating solar-panel installation as claimed in claim 1 comprises:
a plurality of supplementary panel-supporting brackets; and
the plurality of supplementary panel-supporting brackets being arranged in a grid configuration around the primary panel-supporting bracket.

10. The support structure for maximizing solar-panel efficiency and facilitating solar-panel installation as claimed in claim 10 comprises:
an arbitrary row of panel-supporting brackets from the grid configuration being positioned coplanar to each other;
an adjacent row of panel-supporting brackets from the grid configuration being positioned coplanar to each other; and
the arbitrary row of panel-supporting brackets and the adjacent row of panel-supporting brackets being positioned offset from each other by a fluid-bypass gap.

11. A support structure for maximizing solar-panel efficiency and facilitating solar-panel installation comprises:
a support pole;
a primary panel-supporting bracket;
an extension arm;
an extension leg;
a plurality of supplementary panel-supporting brackets;
the support pole being terminally positioned to the extension leg;
the support pole being hingedly connected to the extension leg about a first rotation axis;
the first rotation axis being positioned perpendicular to the support pole;
the extension arm being terminally connected to the support pole, opposite to the extension leg;
the primary panel-supporting bracket being terminally positioned to the extension arm opposite the support pole;
the primary panel-supporting bracket being pivotally mounted to the extension arm about a second rotation axis and a third rotation axis;
the second rotation axis being positioned parallel with the support pole;
the third rotation axis being positioned perpendicular to the second rotation axis;
the plurality of supplementary panel-supporting brackets being arranged in a grid configuration around the primary panel-supporting bracket;
an arbitrary row of panel-supporting brackets from the grid configuration being positioned coplanar to each other;
an adjacent row of panel-supporting brackets from the grid configuration being positioned coplanar to each other; and
the arbitrary row of panel-supporting brackets and the adjacent row of panel-supporting brackets being positioned offset from each other by a fluid-bypass gap.

12. The support structure for maximizing solar-panel efficiency and facilitating solar-panel installation as claimed in claim 11 comprises:
a first linear actuator;
an extension foot;
the extension foot being laterally connected to the extension leg, offset from the first rotation axis;
the extension foot being positioned perpendicular to the first rotation axis;
the first linear actuator being positioned adjacent to the first rotation axis;
a proximal end of the first linear actuator being hingedly and laterally attached to the support pole, offset from the first rotation axis; and
a distal end of the first linear actuator being hingedly attached to the extension foot, offset from the extension leg.

13. The support structure for maximizing solar-panel efficiency and facilitating solar-panel installation as claimed in claim 11 comprises:
a first locking flange;
a second locking flange;
a plurality of fasteners;
the first locking flange being laterally connected around the support pole;
the second locking flange being laterally connected around the extension leg;
the first locking flange and the second locking flange being pressed against each other;
the first locking flange and the second locking flange being engaged to each other by the plurality of fasteners; and
the extension arm being positioned collinear with the support pole.

14. The support structure for maximizing solar-panel efficiency and facilitating solar-panel installation as claimed in claim 11 comprises:
the primary panel-supporting bracket comprises a clevis, an alignment rod, and a panel-mounting structure;
the clevis being connected adjacent to extension arm, offset the support pole;
the alignment rod being rotatably connected into the clevis about the second rotation axis; and
the panel-mounting structure being rotatably connected to the alignment rod about the third rotation axis.

15. The support structure for maximizing solar-panel efficiency and facilitating solar-panel installation as claimed in claim 14 comprises:
a second linear actuator;
a spacing rod;
the spacing rod being laterally connected to the alignment rod, offset from the clevis;
a proximal end of the second linear actuator being hingedly and laterally attached to the spacing rod, offset from the alignment rod; and
a distal end of the second linear actuator being hingedly attached to the panel-mounting structure, offset from the alignment rod.

16. The support structure for maximizing solar-panel efficiency and facilitating solar-panel installation as claimed in claim 14 comprises:
a third linear actuator;
a swivel arm;
a first end of the swivel arm being hingedly and laterally connected to the extension arm;
a second end of the swivel arm being laterally connected to the third linear actuator;
the second end of the swivel arm being positioned adjacent to the proximal end of the third linear actuator, offset from the second rotation axis; and
a distal end of the third linear actuator being hingedly and laterally attached to the alignment rod, offset from the second rotation axis.
